(19) United States
(12) Patent Application Publication
(10) Pub. No.: US 2008/0157340 A1
(43) Pub. Date: Jul. 3, 2008

(54) RF module package

(75) Inventors: Wen-Kun Yang, Hsin-Chu City (TW); Chun-Hui Yu, Tainan City (TW); Chih-wei Lin, Gueiren Township (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/980,498

(22) Filed: Oct. 31, 2007

Related U.S. Application Data
(63) Continuation-in-part of application No. 11/647,448, filed on Dec. 29, 2006.

(51) Int. Cl. H01L 23/48; H01L 21/60

(52) U.S. Cl. 257/691; 257/766; 438/107; 257/E23.01; 257/E21.506

(57) ABSTRACT

The present invention discloses a structure of package comprising: a substrate with die receiving through holes, conductive connecting through holes and contact metal pads; a base attached on a portion of the lower surface of the substrate; multiple dice disposed within the die receiving through holes and attached on the base; multiple dielectric layers formed on the multiple dice and the substrate; multiple re-distribution layers (RDL) formed within the multiple dielectric layers and coupled to the multiple dice; a top layer formed over the RDL; and pluralities of terminal pads formed on the backside of the substrate and coupled to the RDL through the connecting through holes. The RDL is made from an alloy comprising Ti/Cu/Au alloy or Ti/Cu/Ni/Au alloy.

### CROSS-REFERENCE

The present application is a continuation-in-part (CIP) application of a pending U.S. application Ser. No. 11/647,448, entitled “RF Module Package”, and filed on Dec. 29, 2006, which is incorporated here in by reference in its entirety.

### FIELD OF THE INVENTION

### This invention relates to a structure of package, and more particularly to a RF (radio frequency) module package with die receiving through-hole of substrate to improve the reliability and to reduce the device size.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

The MCM may also contain passive components, e.g. capacitors, inductors, and resistors. A typical arrangement for RF package is an RF circuit chip and a capacitor mounted on the substrate. The substrate can be laminate, ceramic, silicon, or other appropriate material. It is because the rapid development of communication technology, the RF package is more important than ever. The requirements for the RF module includes high circuit density, low electrical loss, excellent dimensional control, high heat dissipation, robust substrate, higher reliability on board and lower cost. However, the prior RF module package employs LTCC and the disadvantage is listed as follows; Low On Board Reliability (TCT); Need extra metal plate for heat dissipation, Long manufacturing cycle; Higher manufacturing cost; IC need to be packaged in advance; Still need wire bonding or SMT process; Thick package body (˜1.4 mm).

Therefore, the present invention provides a RF module package to fit the requirement above.

### SUMMARY OF THE INVENTION

The object of the present invention is to provide RF module package with excellent thermal dissipation, CTE performance and shrinkage size.

An RF module package comprising: a substrate with die receiving through holes and conductive connecting through holes, wherein the conductive connecting through holes couple the first contact pads on the upper surface of the substrate and the second contact pads on the lower surface of the substrate; multiple dice having metal pads (I/O pads) on active surface and disposed within the die receiving through holes; a conductive slice attached on the back side of the dice and a portion of the lower surface of the substrate, wherein the multiple dice are attached on the conductive slice; multiple dielectric stacking structure stacked on the multiple dice and the substrate; multiple re-distribution layers (RDL) formed within the multiple dielectric stacking structure and coupled to the metal pads of the multiple dice and the first contact pads of the substrate; and a top layer formed over the multiple dielectric stacking structure. Molecular fans are formed on the top layer. Conductive bumps may be coupled to the pluralities of terminal pads (second contact pads and conductive slice on back side).

### BRIEF DESCRIPTION OF THE DRAWINGS

FIG. 1 illustrates a cross-sectional view of a structure of RF module package according to the present invention. (LGA type)

FIG. 2 illustrates a cross-sectional view of a structure of RF module package according to the present invention. (BGA type)

FIG. 3 illustrates a top view of a structure of RF module package according to the present invention.

FIG. 4 illustrates a top view of the RF module package according to the present invention.

FIG. 5 illustrates a top view of the RF module package according to the present invention.

FIG. 6 illustrates a bottom view of the RF module package according to the present invention.

FIG. 7 illustrates a cross-sectional view of a structure of RF module package on board according to the present invention. (BGA type)

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

The present invention discloses a structure of RF module package utilizing a substrate having predetermined the first contact metal pads 3 formed thereon and a pre-formed die receiving through holes 4 formed into the substrate 2. Multiple dice 6 (chip a, chip b and chip n) have metal pads (I/O pads) 10 on active surface and are disposed within the die receiving through holes of the substrate, and an elastic core paste material (act as die attached materials) 13 is filled into the space between die edge and side wall of die receiving through holes of the substrate. A photosensitive material is coated over the die and the pre-formed substrate (includes the core paste area). Preferably, the material of the photosensitive material is formed of elastic material.

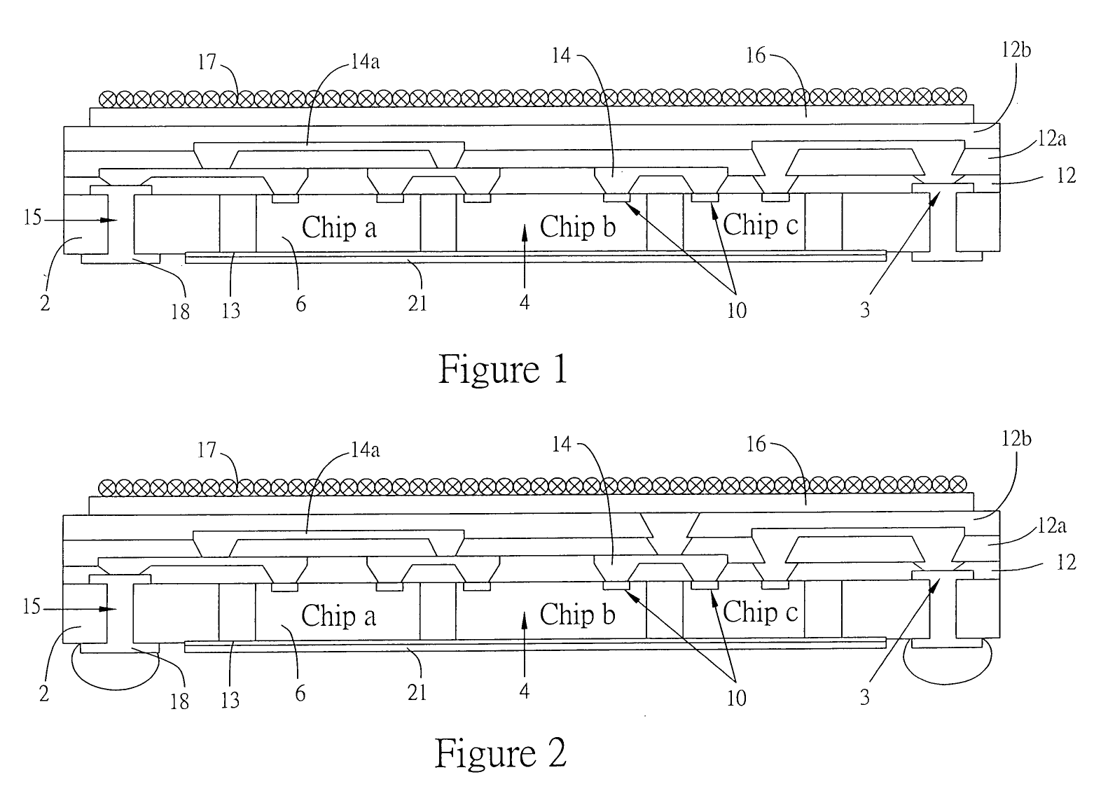

FIG. 1 illustrates a cross-sectional view of RF module package in accordance with one embodiment of the present invention. As shown in the FIG. 1, the structure includes a substrate 2 having a first contact metal pads 3 (for organic substrate) and die receiving through holes 4 formed therein to receive multiple dice 6. The die receiving through holes 4 are formed from the upper surface of the substrate through the substrate to the lower surface. The die receiving through holes 4 are pre-formed within the substrate 2. A conductive (metal or alloy) slice 21 is attached on the lower surface of the dice 6, the core paste material 13 and the substrate 2, and preferably, the conductive slice 21 is formed by electro-plating Cu/Au or Cu/Ni/Au and the thickness of the conductive slice 21 can be 10 um to 60 um.

The dice 6 are disposed within the die receiving through holes 4 on the substrate 2. As known, metal pads (I/O Bonding pads) 10 are formed on the dice 6. A first photosensitive layer or dielectric layer 12 is formed over the multiple dice 6 and the upper surface of substrate and core paste material 13 is filled within the space between the dice 6, die edge and the sidewalls of the die receiving through holes 4. Pluralities of openings are formed within the dielectric layer 12 through the lithography process or exposure and develop procedure. The pluralities of openings are aligned to the metal pads or I/O pads 10 and the first contact metal pads 3 on the substrate, respectively. The first RDL (redistribution layer) 14, also referred to as conductive trace 14, is formed on the first dielectric layer 12 by removing selected portions of metal layer formed over the layer 12, wherein the first RDL 14 keep electrically connection with the dice 6 through the metal pads (I/O pads) 10 and the first contact metal pads 3. A part of the material of the first RDL will re-fills into the openings in the first dielectric layer 12. The first contact metal pads 3 are coupled to the second contact metal pads 18 through the conductive connecting through holes 15 in the substrate 2 (which can be pre-formed).

By the same way, a second dielectric layer 12a with second RDL 14a and a second dielectric layer 12b with top layer 16 are subsequently formed over the first dielectric layer 12, thereby constructing a stacked interconnection structure with multi-layers RDL. As it can be seen, the second RDL 14a couples the dice through first RDL 14, and the top layer 16 may couple to either first RDL 14 or second RDL 14a if the conductive materials are used.

The top layer 16 (for example, a conductive (metal or alloy) layer 16) covers the third dielectric layer 12b. A heat sink 17 is formed atop the top layer 16 for thermal dissipation. Preferably, the heat sink 17 is made of molecular fan. The molecular groups vibrate with more energy at higher surface temperature. The vibration can relax after emitting a phone, infrared radiation, allowing the substrate to release energy even when the surroundings are also warm. The top layer 16 can also be made of other materials such as epoxy type FR4, FR5, polyimide (PI), BT or ceramic materials with adhesion material together. The second (terminal) contact metal pads 18 are located under the substrate 2 and connected to the first RDL 14 and the first contact metal pads 3 of the substrate.

The dielectric layer 12 is formed atop of the multiple dice 6 and substrate 2 and refilling material such as elastic core paste. It acts as a buffer to absorb the thermal mechanical stress between the dice 6 and substrate 2 during temperature cycling due to the dielectric layer 12 is elastic property. Furthermore, it may only cover the surfaces of the dice 6 and the core paste material 13 except the substrate 2 due to the CTE of substrate 2 (for example, made of FR4/FR5/BT) is same as the CTE of PCB (mother board). The aforementioned structure constructs LGA type package. The first contact metal pads 3 may be formed within the dielectric layer 12, over the substrate 2 and maybe aligned to the second (terminal) contact metal pad 18. An alternative embodiment can be seen in FIG. 2, conductive balls 20 are formed on the second (terminal) contact metal pads 18. This type is called BGA type. The other parts are similar to FIG. 1, therefore, the detailed description is omitted. The second (terminal) contact metal pads 18 act as the UBM (under ball metal) under the BGA scheme in the case.

Preferably, the material of the substrate 2 is organic substrate like epoxy type FR5, polyimide (PI), BT, PCB with defined through holes or Cu metal with pre etching circuit. Preferably, the CTE is the same as the one of the mother board (PCB). Preferably, the organic substrate with high Glass transition temperature (Tg) are epoxy type FR5 or BT (Bismaleimide triazine) type substrate. The Cu metal (CTE around 16) can be used also. The glass, ceramic, silicon can be used as the substrate. The elastic core paste is formed of silicone rubber elastic materials, it maybe the same with the die attached materials.

It is because that the CTE (X/Y direction) of the epoxy type organic substrate (FR5/BT) is around 16 and the CTE of the tool for chip redistribution is around 5 to 8 by employing the glass materials as the tool. The FR5/BT is unlikely to return to original location after the temperature cycling (the temperature is close to Glass transition temperature Tg) that causes the die shift in panel form during the WLP process which needs several high temperature process. For example, the dielectric layers formation, the heat curing die attached materials etc., once the base is attached on the die back side and substrate with die redistribution tool together; the base is used to make sure organic substrate can keep the die at the original location and no any warp occurs during process.

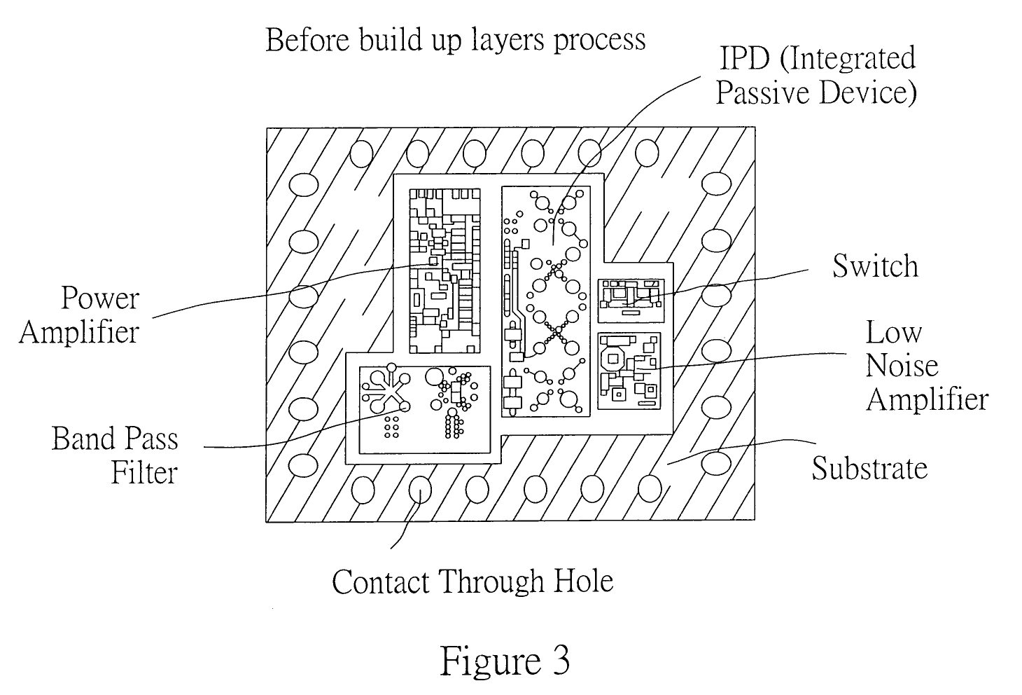

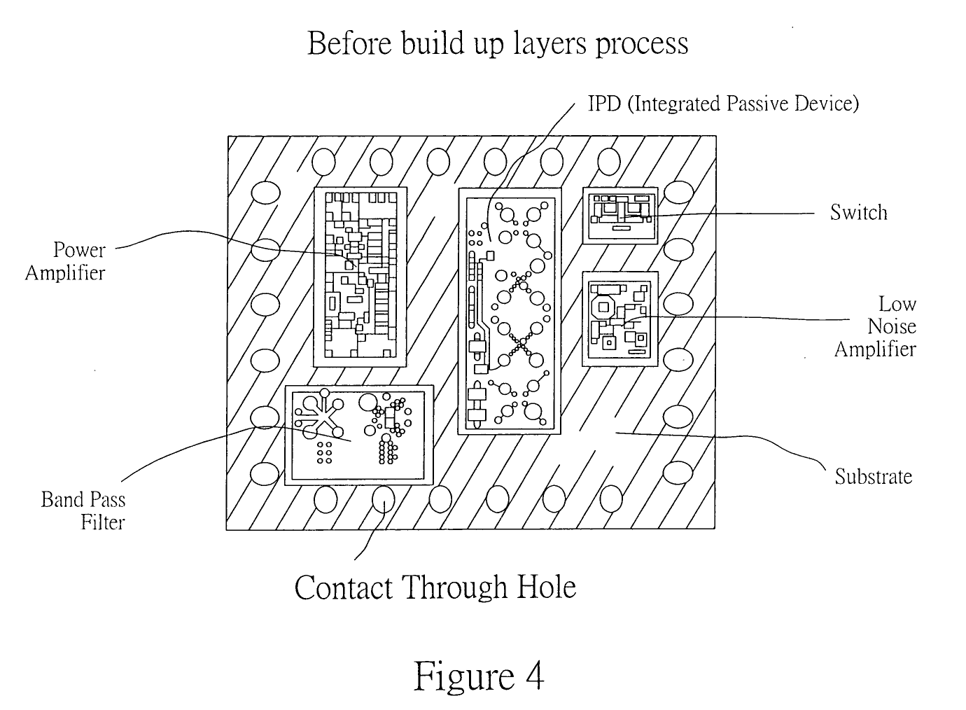

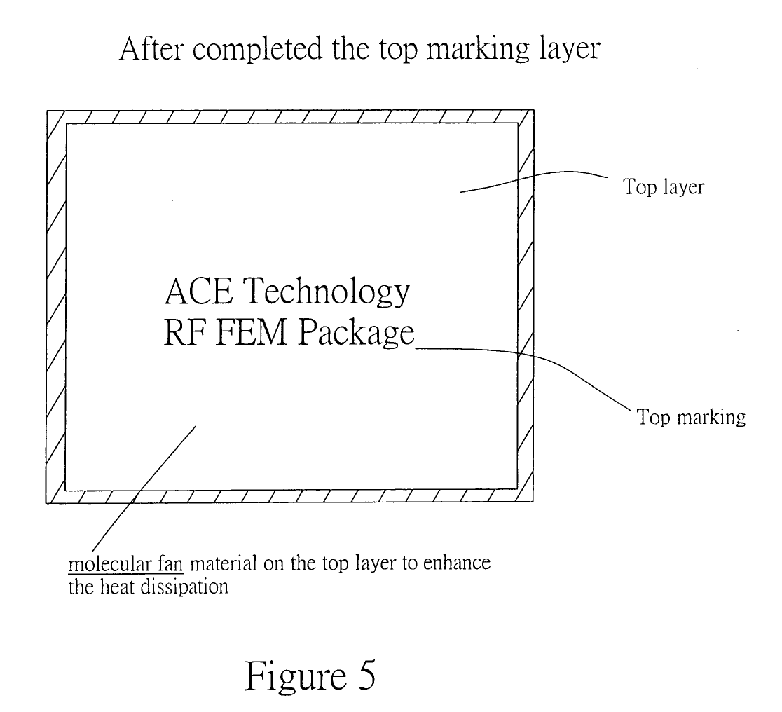

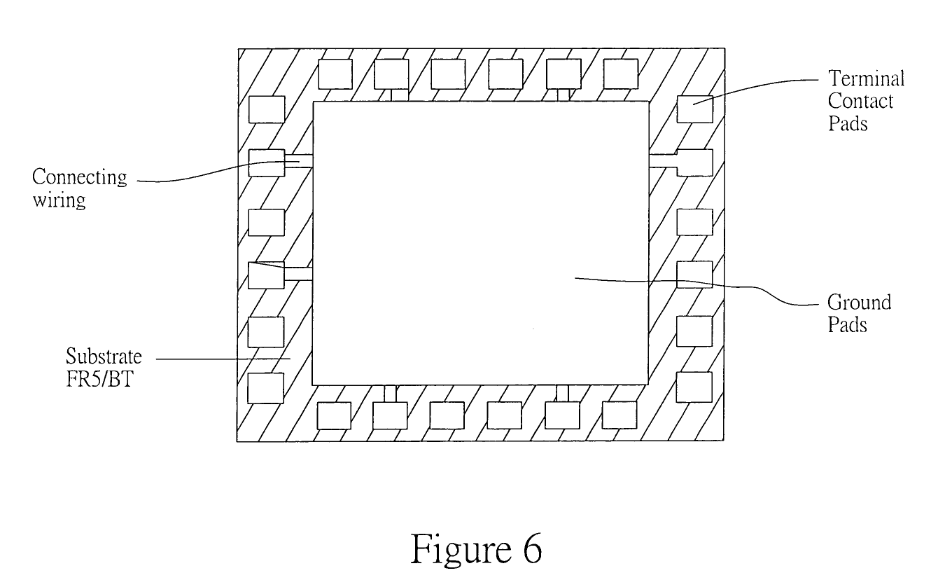

The substrate could be round type such as wafer type, the diameter could be 200, 300 mm or higher. It could be employed for rectangular type such as panel form. The substrate 2 is pre-formed with die receiving through holes 4. FIG. 3 is the top view of RF module package. The package includes power amplifier, band pass filter, switch, low noise amplifier formed on the substrate. FIG. 4 illustrates further embodiment of the present invention. A text, character, logo may be marked on the top layer 16 as shown in FIG. 5. The top layer can be a ground shielding, heat sink. FIG. 6 is the bottom view of the present invention.

In one embodiment of the present invention, the dielectric layer 12, 12a, 12b are preferably an elastic dielectric material which is made by silicone dielectric based materials comprising siloxane polymers (SINR), Dow Corning WL5000 series, and the combination thereof. In another embodiment, the dielectric layer is made by a material comprising, polyimide (PI) or silicone resin. Preferably, it is a photosensitive layer for simple process. In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer 12, 12a, 12b depends on the stress accumulated in the RDL/dielectric layer interface during temperature cycling test.

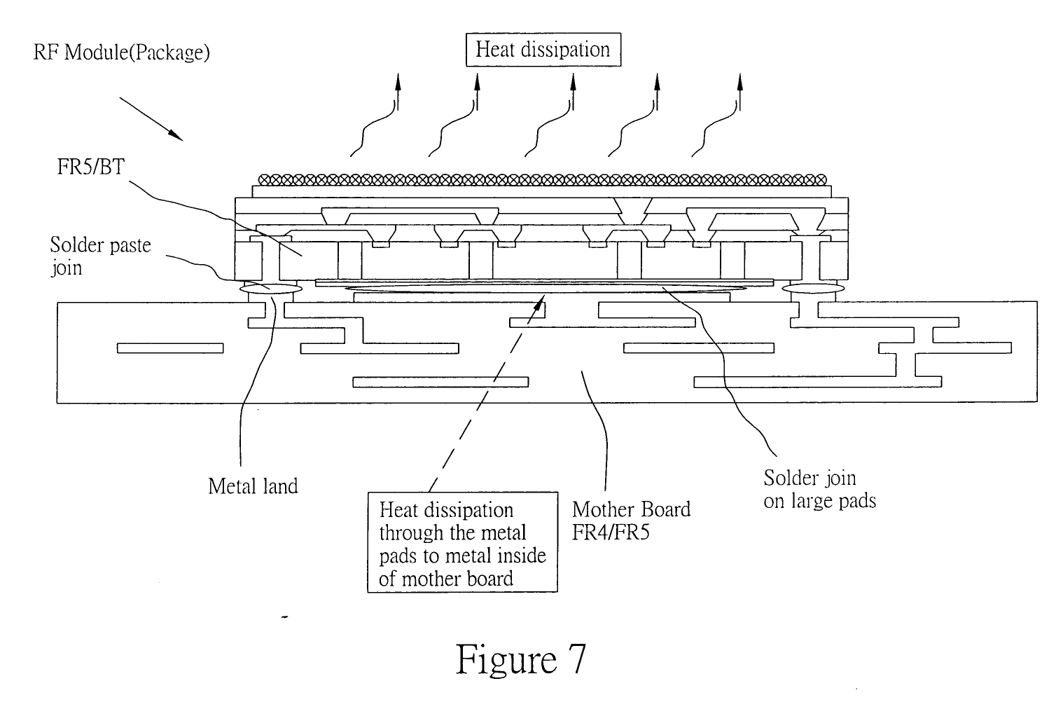

Please refer to FIG. 7, it illustrates the major portions that associate with the CTE issue. The silicon dice (CTE is ˜2.3) is packaged inside the package. FR5 or BT organic epoxy type material (CTE˜16) is employed as the substrate and its CTE is the same as the PCB or Mother Board. The space (gap) between the dice and the substrate is filled with filling material (prefer the elastic core paste) to absorb the thermal mechanical stress due to CTE mismatching (between die and the epoxy type FR5/BT). Further, the dielectric layers 12 include elastic materials to absorb the stress between the die pads and the PCB. The RDL metal is Cu/Au materials and the CTE is around 16 that is the same as the PCB and organic substrate, and the UBM 18 of contact bump is coupled to the first contact metal pads 3 of substrate. The metal land of PCB is Cu composition metal, the CTE of Cu is around 16 that is match to the one of PCB. From the description above, the present invention may provide excellent CTE (fully matching in X/Y direction) solution for the fan-out WLP.

Apparently, CTE matching issue under the build up layers (PCB and substrate) is solved by the present scheme and it provides better reliability (no thermal stress in X/Y directions for terminal pads (solder balls/bumps) on the substrate during on board level condition) and the elastic DL is employed to absorb the Z direction stress in die area. The space (gap) between chip edge and sidewall of through holes of substrate can be used to fill the elastic dielectric materials to absorb the mechanical/thermal stress.

In one embodiment of the invention, the material of the RDLs 14, and 14a comprise Ti/Cu/Au alloy or Ti/Cu/Ni/Au alloy; the thickness of the RDL 24 is between 2 um_and_{—}15 um. The Ti/Cu alloy is formed by sputtering technique also as seed metal layers, and the Cu/Au or Cu/Ni/Au alloy is formed by electroplating; exploiting the electro-plating process to form the RDL can make the RDL thick enough and better mechanical properties to withstand CTE mismatching during temperature cycling. If the structure of FO-WLP utilizes SINR as the elastic dielectric layer and Cu as the RDL, according the stress analysis not shown here, the stress accumulated in the RDL/dielectric layer interface is reduced.

As shown in FIG. 1-2, the RDL 14 fans out of the die and communicates toward the terminal pads at lower surface of substrate. It is different from the prior art technology, the dice 6 is received within the pre-formed die receiving through holes of the substrate, thereby reducing the thickness of the package. The prior art violates the rule to reduce the die package thickness. The package of the present invention will be thinner than the prior art. Further, the substrate is pre-prepared before package. The die receiving through holes 4 are pre-determined. Thus, the throughput will be improved than ever. The present invention discloses a fan-out WLP with reduced thickness and good CTE matching performance.

The present invention includes preparing a dicing sawed wafer in blue tape form (GaAs) and preparing the die redistribution tool (Glass base) with patterned glues and alignment pattern on the tool, followed by employing a pick and place with fine alignment system to pick and place the selected chips on the tool and patterned glues stick the die active surface. The substrate is bonding on the tool and patterned glues stick the substrate. A Vacuum printing is performed to print the core material (silicone rubber) into the gap between the die edge and the side wall of die through holes of substrate. The core paste is cured and special solvent is used to release patterned glues to separate the panel wafer and tool. Thereafter, the panel wafer is cleaned.

The seed metal is sputtered on the back side of the panel. PR is coating and forming the desired pattern. Electro-plating is performed to form the Cu/Ni/Au (˜25 um). The PR is stripped and wet etching is used to form the ground metal pads and terminal pads on the back side of the dice and the substrate. The Glass Carrier is bounded on the back side of panel and UV tape is used to attach the Glass carrier and the Panel for further processes.

The steps to form the RDL includes:
Cleaning the upper side of panel by wet/dry clean;
Coating the dielectric layer 1 and open the bonding pads and metal contact pads on substrate (panel);
Sputtering the Ti/Cu as seed metal layers;
PR coating and to form the RDL pattern;
Electro-plating Cu/Au (˜6 um), and then stripping the PR and wet etching to form the first RDL trace metal;
Coating the dielectric layer 2 and open the contact Vias;
Sputtering the Ti/Cu as seed metal layer;
PR coating and forming the RDL pattern (including the inductors);
Electro-plating Cu/Au (˜6 um), then removing PR and wet etching to form the second RDL trace metal;
[Coating the dielectric layer 3 (thick than 50 um) and opening the ground contact Vias;
Sputtering the seed metal layers (Ti/Cu);
PR coating and forming the top ground metal pattern;
Electro-plating Cu/Ni/Au (˜15 um), PR strip and wet etching to form the ground pads on top (including the character of top mark);] The aforementioned steps [ ] may be replaced as attaching the top layer with elastic adhesion material on the top of the second RDL and portion of dielectric layer 2 and curing the elastic adhesion materials to form the top layer.
Coating the heat sink materials—molecular fan on the top metal (˜10 um) to enhance the heat dissipation.

Then, the Glass carrier is removed by special solvent or UV; the panel is taping on the blue tape in flame type. The panel final testing is performed by using the flame type probing system. The panel (substrate—FR5/BT) is cut to separate the package unit.

The advantages of the present inventions are:
Low Cost: simple materials and process;
Better performance on board Reliability (TCT) due to the CTE of Substrate FR5/BT matches to the one of PCB FR4/FR5 (˜16);
Better Thermal Management-employing metal to handle heat dissipation; Copper thermal conductive k=380, LTCC ceramic k=3-5, and most of heat is conducted from the conductive slice to the circuit trace of PCB and dissipated to the outside.
Low Electrical Loss, high Q;
Dielectric materials with low k (<3) data, Using GaAs material for IPD die, the k value is lower compare to dielectric constant for Ceramic k=3-5;
Short manufacturing cycle time due to apply simple process steps.

Elastic core paste (resin, epoxy compound, silicone rubber, etc.) is refilled the space between the dice edge and the sidewall of the through holes for thermal stress releasing buffer in the present invention, then, vacuum heat curing is applied. CTE mismatching issue is overcome during panel form process (using the base with lower CTE that is close to silicon die and substrate) and the deepness between die and substrate FR5/BT is almost same level, the surface level of die (active surface side) and substrate can be the same after the die and substrate are attached on the base, and separated the panel wafer from the die redistribution tool. Only silicone dielectric material (preferably SINR) is coated on the active surface and/or the substrate (preferably FR45 or BT) surface. The contact pads are opened by using photo mask process only due to the dielectric layer (SINR) is photosensitive layer for opening the contacting open. The die attached material is printed into the edge of the dice and the gap of the substrate to be bonded together. The reliability for both package and board level is better than ever, especially, for the board level temperature cycling test, it was due to the CTE of substrate and PCB mother board are identical, hence, no thermal mechanical stress be applied on the solder bumps/balls; the previous failure mode (solder ball crack) during temperature cycling on board test were not obvious. The cost is low and the process is simple. It is easy to form the multi-chips package in the present invention.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of RF module package comprising:
a substrate with at least die receiving through holes and conductive connecting through holes; wherein said conductive connecting through holes couple first contact pads on the upper surface of said substrate to second contact pads on the lower surface of said substrate;
multiple dice with metal pads and disposed within said die receiving through holes;
a conductive slice attached on the back side of said multiple dice and a portion of the lower surface of said substrate, wherein said multiple dice are attached on said conductive slice;
multiple dielectric layers stacking structure stacked on said multiple dice and said substrate;
multiple re-distribution layers (RDL) formed within said multiple dielectric stacking structure and coupled to the metal pads of said multiple dice and the first contact pads of said substrate; and
a top layer formed over said multiple dielectric stacking structure.

2. The structure of claim 1, further comprising heat sink materials on said top layer.

3. The structure of claim 2, wherein the materials of said heat sink materials includes molecular cooling fan.

4. The structure of claim 1, wherein the materials of said top layer include metal, epoxy resin, silicone resin, FR4, FR5, polyimide (PI), or BT.

5. The structure of claim 1, further comprising conductive bumps coupled to pluralities of terminal pads and said conductive slice, wherein said pluralities of terminal pads are formed on the lower surface of said substrate and coupled to the second contact pads of said substrate.

6. The structure of claim 1, wherein said multiple dice include the power amplifier, band pass filter, low noise amplifier, switch or integrated passive device (IPD).

7. The structure of claim 1, wherein the materials of said multiple dice include the gallium arsenic (GaAs) and silicon chips.

8. The structure of claim 1, wherein said multiple RDLs include the structure function of inductors, capacitors or resistors.

9. The structure of claim 1, wherein said multiple RDL is made from an alloy comprising Ti/Cu/Au alloy or Ti/Cu/Ni/Au alloy.

10. The structure of claim 1, wherein the material of said substrate includes epoxy type FR5, FR4, polyimide (PI), BT, silicon, PCB (print circuit board) materials, glass, ceramic, alloy or metal.

11. The structure of claim 1, further comprising core paste material filled into the space (gap) between the die edge and sidewall of the die receiving through holes of said substrate.

12. The structure of claim 1, wherein the material of a dielectric layer in said multiple dielectric stacking structure includes an elastic dielectric layer, a photosensitive layer, a silicone dielectric based layer, a siloxane polymer (SINR) layer, a polyimides (PI) layer or silicone resin layer.

13. The structure of claim 1, wherein the material of said conductive metal includes Cu.

14. A method for forming RF module package comprising:
providing a substrate with die receiving through holes, conductive connecting through holes and contact metal pads on both side;
preparing a die redistribution tool with patterned glues and alignment pattern on said die redistribution tool, followed by employing a pick and place with fine alignment system to pick and place the selected dice on said die redistribution tool and said patterned glues sticking active surfaces of said dice;
bonding said substrate on said die redistribution tool and said patterned glues sticking said substrate;
printing core paste material into the gap between the dice edge and side wall of said die receiving through holes and portion of the backside of said dice;
separating said substrate with embedded multiple dice from said die redistribution tool by releasing said patterned glues;
sputtering seed metal layers on the backside of said substrate and the backside of said multiple dice;
forming a contacting structure (ground metal pads and terminal pads) on the backside (lower surface) of said substrate and the backside of said multiple dice;
forming multiple dielectric stacking structure with multiple RDLs on the upper surface of said substrate and said multiple dice; and
forming a top layers on top of said multiple dielectric stacking structure.

15. The method of claim 14, further comprising coating heat sink materials on top layer to enhance heat dissipation.

16. The method of claim 14, further comprising forming a conductive bump coupled to said contacting structure.

17. The method of claim 14, further comprising curing said core paste material after filling said core paste material into the space between said dice edge and the sidewall of said die receiving through holes.

18. The method of claim 16, wherein dielectric layer of said multiple dielectric stacking structure includes an elastic dielectric layer, a photosensitive layer, a silicone dielectric based material layer, a polyimides (PI) layer or a silicone resin layer.

19. The method of claim 20, wherein said silicone dielectric based material comprises siloxane polymers (SINR), Dow Corning WL5000 series, or the combination thereof.

20. The method of claim 16, wherein said RDL is made from an alloy comprising Ti/Cu/Au alloy or Ti/Cu/Ni/Au alloy.

21. The method of claim 16, wherein the material of said substrate includes epoxy type FR5, FR4, polyimide (PI), BT, silicon, PCB (print circuit board) materials, glass, ceramic, alloy or metal.

22. A structure of Inter-connecting of semiconductor device package comprising:
a substrate with at least die receiving through holes;
at least a die disposed within said die receiving through holes;
an adhesion material filled into the gap between the edge of said die and the sidewall of said die receiving through holes; and
a conductive slice attached on the backside of said die and covering said adhesion material and a portion of the backside of said substrate, wherein said conductive slice includes seed metal Ti/Cu or Cu layers and plating metal layers Cu/Ni/Au.

23. The structure of claim 22, wherein the thickness of said plating metal layers is around 10 um to 60 um.
